(19) United States
(12) Patent Application Publication
(10) Pub. No.: US 2025/0201591 A1
(43) Pub. Date: Jun. 19, 2025

(54) MANUFACTURING METHOD, SUBSTRATE PROCESSING METHOD, AND CONTROL METHOD OF SUBSTRATE PROCESSING APPARATUS

(71) Applicant: SEMES CO., LTD., Cheonan-si (KR)

(72) Inventors: Do Hyeon YOON, Cheonan-si (KR); Mi So PARK, Cheonan-si (KR)

(73) Assignee: SEMES CO., LTD., Cheonan-si (KR)

(21) Appl. No.: 18/972,029

(22) Filed: Dec. 6, 2024

(30) Foreign Application Priority Data
Dec. 15, 2023 (KR) 10-2023-0183585

(51) Int. Cl. H01L 21/67; H01L 21/02; H01L 21/687

(52) U.S. Cl. CPC H01L 21/67051; H01L 21/02101; H01L 21/67034; H01L 21/68764

(57) ABSTRACT

Disclosed is a method of processing a substrate, the method including: supplying a second treatment liquid of a different type from a first treatment liquid to a first location of a substrate while supplying the first treatment liquid to a second location of a rotating substrate, the first location being closer to a center of the substrate than the second location, in which the nozzle supplying the first treatment liquid is moved while continuing to supply the first treatment liquid after a setting time has elapsed from a time when the second treatment liquid is started to be supplied.

### CROSS-REFERENCE TO RELATED APPLICATIONS

This application claims priority to and the benefit of Korean Patent Application No. 10-2023-0183585 filed in the Korean Intellectual Property Office on Dec. 15, 2023, the entire contents of which are incorporated herein by reference.

### TECHNICAL FIELD

The present invention relates to a manufacturing method, a substrate processing method, and a substrate processing apparatus.

### BACKGROUND ART

To manufacture semiconductor devices, a desired pattern is formed on a substrate, such as a wafer, through various processes such as photography, etching, ashing, ion implantation, and thin film deposition. Various treatment liquids and treatment gas are used in each process, and particles and process by-products are generated during the process. Cleaning processes are performed before and after each process to remove these particles and process by-products from the substrate.

### SUMMARY OF THE INVENTION

The present invention has been made in an effort to provide a manufacturing method, a substrate processing method, and a control method of a substrate processing apparatus that are capable of efficiently processing a substrate.

The present invention has been made in an effort to provide a manufacturing method, a substrate processing method, and a control method of a substrate processing apparatus that are capable of effectively cleaning a substrate.

The present invention has also been made in an effort to provide a manufacturing method, a substrate processing method, and a control method of a substrate processing apparatus that are capable of replacing a rinse liquid supplied to a substrate with an organic solvent to form a uniform organic solvent liquid film on the substrate.

The present invention has also been made in an effort to provide a manufacturing method, a substrate processing method, and a control method of a substrate processing apparatus that are capable of uniformly forming an organic solvent liquid film on a substrate, thereby improving drying efficiency of the substrate by a supercritical fluid.

The problem to be solved by the present invention is not limited to the above-mentioned problems, and the problems not mentioned will be clearly understood by those skilled in the art from the descriptions below.

An exemplary embodiment of the present invention provides a method of processing a substrate, the method including: supplying a second treatment liquid of a different type from a first treatment liquid to a first location of a substrate while supplying the first treatment liquid to a second location of a rotating substrate, the first location being closer to a center of the substrate than the second location, in which the nozzle supplying the first treatment liquid is moved while continuing to supply the first treatment liquid after a setting time has elapsed from a time when the second treatment liquid is started to be supplied.

According to the exemplary embodiment, the nozzle may move in a direction away from the center of the substrate while continuing to supply the first treatment liquid.

According to the exemplary embodiment, the first treatment liquid and the second treatment liquid may be provided to have different surface tension, and the setting time may be set based on a time for the second treatment liquid supplied to the first location to reach the second location.

According to the exemplary embodiment, the setting time may be set as a time immediately before the second treatment liquid supplied to the first location meets the first treatment liquid supplied to the second location, or a time within a threshold time after the first treatment liquid meets the second treatment liquid.

According to the exemplary embodiment, the threshold time may be a time period of no more than 2 seconds after the second treatment liquid supplied to the first location meets the first treatment liquid supplied to the second location.

According to the exemplary embodiment, as a rotation speed of the substrate is higher, the setting time may be set to be shorter.

According to the exemplary embodiment, as a supply flow rate per unit time of the second treatment liquid supplied to the substrate is larger, the setting time may be set to be shorter.

According to the exemplary embodiment, the second treatment liquid may be an organic solvent, and the first treatment liquid may be deionized water.

Another exemplary embodiment of the present invention provides a manufacturing method, including: a liquid treatment operation of supplying a treatment liquid to a rotating substrate to process the substrate; and a drying operation of supplying a supercritical fluid to the substrate to process the substrate, after the liquid treatment operation, in which the liquid treatment operation includes: a first liquid treatment operation of supplying a first treatment liquid to a first location of the rotating substrate and a second position that is farther from a center of the substrate than the first position; and a second liquid treatment operation of supplying a second treatment liquid having different surface tension from the first treatment liquid to the first location of the rotating substrate, and supplying the first treatment liquid to the second location of the rotating substrate, and the second liquid treatment operation includes, after the supply of the second treatment liquid has begun and a setting time has elapsed, moving a nozzle supplying the first treatment liquid in a direction away from the center of the substrate while supplying the first treatment liquid.

According to the exemplary embodiment, the setting time may be set based on a time for the second treatment liquid supplied to the first location to reach the second location.

According to the exemplary embodiment, the setting time may be set as a time immediately before the second treatment liquid supplied to the first location meets the first treatment liquid supplied to the second location, or a time within a threshold time after the first treatment liquid meets the second treatment liquid.

According to the exemplary embodiment, the threshold time may be a time period of no more than 2 seconds after the second treatment liquid supplied to the first location meets the first treatment liquid supplied to the second location.

According to the exemplary embodiment, a movement speed of the nozzle in the second liquid treatment operation may be equal to or lower than a diffusion rate of the second treatment liquid supplied to the first location in the second liquid treatment operation.

According to the exemplary embodiment, the liquid treatment operation further includes a third liquid treatment operation of supplying the second treatment liquid to the first location of the rotating substrate to form a liquid film, after the second liquid treatment operation.

According to the exemplary embodiment, the first treatment liquid may have greater surface tension than the second treatment liquid.

According to the exemplary embodiment, the first treatment liquid may be deionized water, and the second treatment liquid may be isopropyl alcohol.

Still another exemplary embodiment of the present invention provides a control method of a substrate processing apparatus, the substrate processing apparatus including: a substrate support chuck for supporting and rotating a substrate; a first nozzle for supplying a first treatment liquid to the substrate supported on the substrate support chuck; a second nozzle for supplying the first treatment liquid to the substrate supported on the substrate support chuck; and a third nozzle for supplying a second treatment liquid of a type different from the first treatment liquid to the substrate supported on the substrate support chuck, the control method including: supplying, by the first nozzle, the first treatment liquid to a center region of the substrate supported and rotated on the substrate support scale, and supplying, by the second nozzle, the first treatment liquid to a middle region of the substrate supported and rotated on the substrate support chuck, the middle region being a region farther from the center of the substrate than the center region; moving the third nozzle to a top side of the center region of the substrate; supplying, by the third nozzle, the second treatment liquid to the center region of the substrate; and after the third nozzle has begun to supply the second treatment liquid and a setting time has elapsed, moving the second nozzle in a direction away from the center of the substrate, in which the second nozzle continues to supply the first treatment liquid while moving.

According to the exemplary embodiment, the setting time may be set as a time immediately before the second treatment liquid supplied to the center region meets the first treatment liquid supplied to the middle region, or a time within a threshold time after the first treatment liquid meets the second treatment liquid.

According to the exemplary embodiment, the threshold time may be a time period of no more than 2 seconds after the second treatment liquid supplied to the first location meets the first treatment liquid supplied to the second location.

According to the exemplary embodiment, the second nozzle may move along an imaginary arc through a center of the substrate W when viewed from above.

According to the exemplary embodiment of the present invention, it is possible to efficiently treat a substrate.

Further, according to the exemplary embodiment of the present invention, it is possible to efficiently clean a substrate.

Further, according to the exemplary embodiment of the present invention, it is possible to effectively replace a rinse liquid supplied on a substrate with an organic solvent to form a uniform organic solvent liquid film on the substrate.

Further, according to the exemplary embodiment of the present invention, it is possible to uniformly form an organic solvent liquid film on a substrate, thereby improving the drying efficiency of the substrate by a supercritical fluid.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a liquid treating chamber of FIG. 1 according to the exemplary embodiment.

FIG. 3 is a diagram schematically illustrating a drying chamber of FIG. 1 according to the exemplary embodiment.

FIG. 4 is a flowchart schematically illustrating a substrate processing method according to an exemplary embodiment of the present invention.

FIG. 5 is a diagram illustrating a liquid treating chamber performing a first liquid treatment operation of FIG. 4.

FIGS. 6 and 7 are diagrams illustrating a view of the liquid treating chamber performing a second liquid treatment operation of FIG. 4.

FIGS. 8 and 9 are diagrams illustrating the flow of a treatment liquid supplied to a substrate W, and the time of the movement of a second nozzle during the second liquid treatment operation of FIG. 4.

FIG. 10 is a top view of the substrate to be processed when viewed from above.

FIG. 11 is a diagram illustrating a view of the liquid treating chamber performing a third liquid treatment operation of FIG. 4.

FIG. 12 is a diagram illustrating a view of a drying chamber performing a drying operation of FIG. 4.

FIG. 13 is a diagram illustrating a view of a liquid treating chamber performing a substrate processing method according to another exemplary embodiment of the present invention.

FIG. 14 is a diagram illustrating a liquid treating chamber according to another exemplary embodiment of the present invention, and a view of the liquid treating chamber performing a substrate processing method according to another exemplary embodiment.

FIG. 15 is a diagram illustrating a view of a liquid treating chamber performing a substrate processing method according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the following, the present invention will be described hereinafter based on the fact that a substrate W to be treated is a wafer. Further, the present invention will be described hereinafter based on the fact that a pattern PA is formed on the substrate W to be treated. Further, the present invention will be described based on the fact that a substrate processing method is a method of manufacturing a semiconductor device.

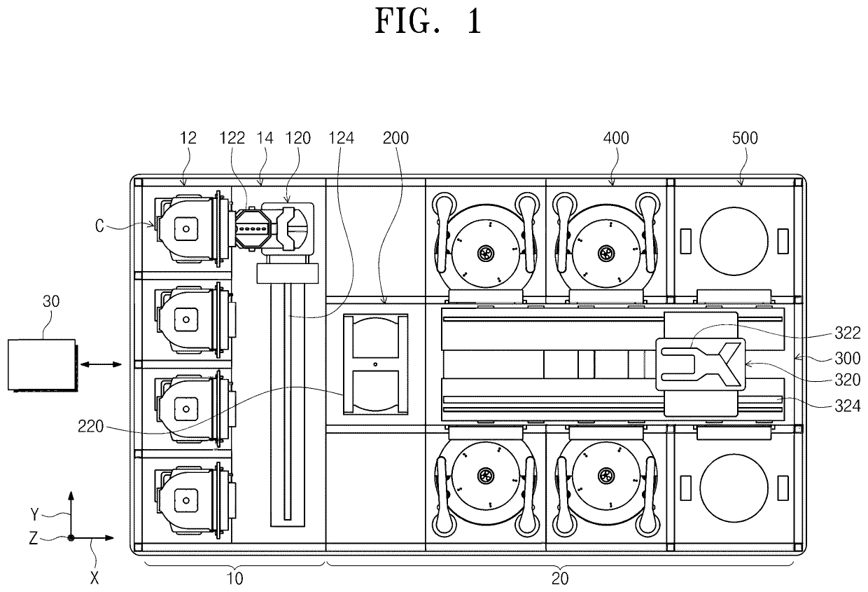

FIG. 1 is a top plan view schematically illustrating a substrate treating apparatus according to an exemplary embodiment of the present invention.

Referring to FIG. 1, a substrate processing apparatus includes an index module 10, a treating module 20, and a controller 30. When viewed from above, the index module 10 and the processing module 20 are disposed along one direction. Hereinafter, the direction in which the index module 10 and the processing module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers the substrate W from the container C in which the substrate W is accommodated to the processing module 20, and accommodates the substrate W that has been completely treated in the processing module 20 in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. A plurality of load ports 12 may be provided, and the plurality of load ports 12 may be disposed along the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate W is placed, and the hand 122 may be provided to be movable forward and backward directions, rotatable about the third direction Z and movable along the third direction Z. A plurality of hands 122 are provided to be spaced apart in the vertical direction, and the hands 122 may move forward and backward independently of each other.

The processing module 20 includes a buffer unit 200, a transfer chamber 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer chamber 300 transfers the substrate W between the buffer unit 200, the liquid treating chamber 400, and the drying chamber 500.

The buffer unit 200 includes a plurality of buffers 220 on which the substrate W is placed. The buffers 220 may be disposed to be spaced apart from each other along the third direction Z. The buffer 220 may be a substrate holder that supports the bottom surface of the substrate W. The buffer 220 may be provided in the form of a support shelf that supports the bottom surface of the substrate W.

A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side portion of the transfer chamber 300. The liquid treating chamber 400 and the transfer chamber 300 may be disposed along the second direction Y. The drying chamber 500 and the transfer chamber 300 may be disposed along the second direction Y. The buffer unit 200 may be located at one end of the transfer chamber 300.

According to the example, the liquid treating chambers 400 are disposed on both sides of transfer chamber 300, and the drying chambers 500 are disposed on both sides of the transfer chamber 300, and the liquid treating chambers 400 may be disposed closer to the buffer unit 200 than the drying chambers 500. At one side of the transfer chamber 300, the liquid treating chambers 400 may be provided in an arrangement of A×B (each of A and B is 1 or a natural larger than 1) in the first direction X and the third direction Z. Further, at one side of the transfer chamber 300, the drying chambers 500 may be provided in number of C×D (each of C and D is 1 or a natural number larger than 1) in the first direction 92 and the third direction 96. Unlike the above, only the liquid treating chambers 400 may be provided on one side of the transfer chamber 300, and only the drying chambers 500 may be provided on the other side of the transfer chamber 300.

The transfer chamber 300 includes a transfer robot 320. A guide rail 324 of which a longitudinal direction is provided in the first direction X is provided in the transfer chamber 300, and the transfer robot 320 may be provided to be movable on the guide rail 324. The index robot 320 includes a hand 322 on which the substrate W is placed, and the hand 322 may be provided to be movable forward and backward directions, rotatable about the third direction Z and movable along the third direction Z. A plurality of hands 322 are provided to be spaced apart in the vertical direction, and the hands 322 may move forward and backward independently of each other.

The controller 30 may control the substrate processing apparatus. The controller 30 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treatment recipe, for executing the process in each component according to various data and treatment conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The controller 30 may control the configurations of the substrate processing apparatus to perform a substrate treating method described below. For example, the controller 30 may generate control commands to control the transfer chamber 300, the liquid treating chamber 400, and the drying chamber 500.

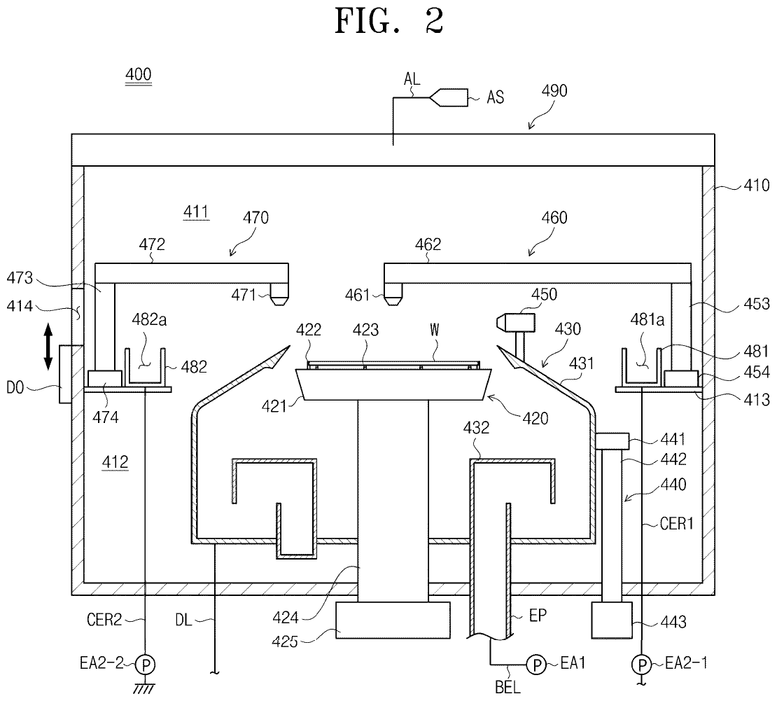

FIG. 2 is a diagram schematically illustrating a liquid treating chamber of FIG. 1 according to the exemplary embodiment.

Referring to FIG. 2, the liquid treating chamber 400 according to the exemplary embodiment of the present invention may treat the substrate W by supplying the substrate W with a treatment liquid. The treatment liquid supplied to the substrate W may be a cleaning solution that cleans the substrate W. The cleaning solution may be deionized water or an organic solvent. The organic solvent may be a solvent containing alcohol. The organic solvent may be isopropyl alcohol (IPA).

The liquid treating chamber 400 may include a housing 410, a support unit 420, a bowl 430, a lifting unit 440, a first nozzle 450, a second liquid supply unit 460, a third liquid supply unit 490, a first nozzle waiting cup 481, a second nozzle waiting cup 482, and a downflow unit 490.

The housing 410 may provide a space in which the substrate W is treated, and a space in which some of the configurations of the liquid treating chamber 400 are arranged. The housing 410 may provide an upper space 411, which is a treatment space in which the substrate W is treated, and a lower space 412, which is located below the upper space 411. The upper space 411 and the lower space 412 may be compartmentalized by a compartment plate 413 disposed within the housing 410. The compartment plate 413 may be a plate with an open center region when viewed from above.

On one side of the housing 410, an entrance opening 414 may be formed for the substrate W to be introduced into the upper space 411 and for the substrate W to be removed from the upper space 411. The entrance opening 414 may be selectively opened and closed by a door DO, which may be a shutter. The door DO may be configured to be movable in an up and down direction. For example, the door DO may be configured to be moved in an up and down direction by an electric motor, a pneumatic/hydraulic cylinder, or the like.

The support unit 420 may be configured to support and rotate the substrate W in the space provided by the housing 410. The support unit 420 may include a rotation plate 421, a rotation shaft 424, and a rotation driver 425. The support unit 420 may be a substrate support chuck configured to support a substrate and rotate the supported substrate.

The rotation plate 421 may have a substantially circular plate shape when viewed from above. The rotation plate 421 may have the shape of a top surface that is wide and a bottom surface that is narrow. In the rotation plate 421, a chuck pin 422 and a support pin 423 may be installed. The chuck pins 422 may be provided in plurality. A rotation axis C of the rotation plate 421 may be aligned with the center of the substrate W.

The chuck pins 422 may be configured to support the bottom face and the side portions of the edge of the substrate W. The chuck pins 422 may be configured to be movable in a direction that is closer to the center of the rotation plate 421 or a direction that is away from the center of the rotation plate 421, when viewed from above. The chuck pins 422 may be configured to be movable in a direction that is closer to the center of the rotation plate 421 or in a direction that is away from the center of the rotation plate 421 by a drive mechanism, such as a motor or cylinder, provided within the rotation plate 421. When the chuck pin 422 is moved in the direction closer to the center of the rotation plate 421 and is positioned in a chucking position, the substrate W may be chucked onto the rotation plate 421. Conversely, when the chuck pin 422 moves in the direction away from the center of the rotation plate 421 and is positioned in a de-chucking position, the substrate W may be de-chucked from the rotation plate 421.

The support pins 423 may be configured to support the bottom face of the substrate W. The support pins 423 may be provided in plurality, and may be configured to support different points on the bottom face of the substrate W, respectively. The support pins 423 may be arranged while being spaced apart from each other along the circumferential direction when viewed from above.

The lower portion of the rotation plate 421 may be coupled with the rotation shaft 424. The rotation shaft 424 may be rotated clockwise or counterclockwise by receiving drive force from the rotation driver 425, which may be a hollow motor.

The bowl 430 may provide a space in which the substrate W is treated. The bowl 430 may have a cup shape with an open top. The bowl 430 may function as a liquid receiving part to collect the treatment liquid that is dispersed from the substrate W when the liquid supply unit 450, described later, supplies the treatment liquid to the rotating substrate W.

The bowl 430 may include an outer bowl 431 and an inner bowl 432. The outer bowl 431 and the inner bowl 432 may include a bottom portion, a side portion extending upwardly from the bottom portion, and a top portion extending to be sloped from the side portion in a direction closer to the rotation plate 421. The side portion may be coupled with the lifting unit 440 described later. The inner bowl 432 may be a bowl disposed on the inner side of the outer bowl 431. The inner bowl 432 may be connected to an exhaust pipe EP capable of exhausting the downflow DF supplied to the upper space 411 that is the treatment space. The exhaust piping EP may be connected to a first pressure reducing device EA1, which may be a pump, via a bowl exhaust line BEL.

The first pressure reducing device EA1 may be configured to exhaust the atmosphere of the space provided by the housing 410 (e.g., the upper space 411) at all times at a preset exhaust flow rate per unit time.

The treatment liquid may be collected between the outer bowl 431 and the inner bowl 432. The collected treatment liquid may be discharged to the outside of the liquid treating chamber 400 via a drain line DL connected to the bottom portion of the outer bowl 431.

Additionally, the downflow DF supplied by the downflow unit 490 described later may be exhausted through the space between the outer bowl 431 and the inner bowl 432. The downflow DF may pass between the outer bowl 431 and the inner bowl 432 and be exhausted to the outside of the liquid treating chamber 400 via the exhaust pipe EP and the bowl exhaust line BEL.

The lifting unit 440 may be configured to change the relative height of the bowl 430 and the rotation plate 421. The lifting unit 440 may be configured to move the bowl 430 in an up and down direction, thereby changing the relative height of the bowl 430 and the rotation plate 421. The lifting unit 440 may include a fixing bracket 441, a lifting shaft 442, and a lifting driver 443. The lifting driver 443, which may be a motor, or a pneumatic/hydraulic cylinder, may move the fixing bracket 441 connected to the lifting shaft 442 in the up and down direction. The fixing bracket 441 is coupled to a side portion of the outer bowl 431, and is capable of moving both the outer bowl 431 and the inner bowl 432 in the up and down direction.

The first nozzle 450, the second liquid supply unit 460, and the third liquid supply unit 470 are supported on the support unit 420 and may supply a treatment liquid to the rotating substrate W to liquid-treat the substrate W. The first nozzle 450, the second liquid supply unit 460, and the third liquid supply unit 470 may be collectively referred to as the liquid supply units. The liquid supply unit may be configured to process the substrate W by supplying a rinse liquid that cleans the supported substrate W, and an organic solvent that cleans the substrate W and is replaced with the rinse liquid.

The first nozzle 450 may be installed on the bowl 430. The first nozzle 450 may be installed on the bowl 430 to supply a first treatment liquid to a center region (an example of a first location) of the substrate W supported on the support unit 420. A first treatment liquid supplied by the first nozzle 450 may be deionized water (DI Water, DIW).

In the exemplary embodiment, the present invention has been described based on the case where the first nozzle 450 is installed on the bowl 430 and is fixed in position, but is not limited thereto. For example, the first nozzle 450 may be fixedly installed in a configuration other than the bowl 430, or may be configured to be changeable in position, such as a second nozzle 461 or a third nozzle 471 described later.

The second liquid supply unit 460 may include a second nozzle 461, a second arm 462, a second movement shaft 463, and a second movement driver 464. The second movement driver 464 may rotate the second movement shaft 463 in a direction perpendicular to the ground as an axis of rotation. One end of the second arm 462 is connected to one end of the second movement shaft 463, such that the position of the other end of the second arm 462 may be changed by rotation of the second movement shaft 463. The second nozzle 461 may be installed on the other end of the second arm 462. Accordingly, the second nozzle 461 may scan in (moving closer to the center of the substrate W) or scan out (moving further away from the center of the substrate W) motion. The second nozzle 461 may be movable along an imaginary arc through the center of the substrate W when viewed from above.

The second nozzle 461 may supply the first treatment liquid to a middle region (an example of a second location) of the substrate W supported on the support unit 420. The first treatment liquid supplied by the second nozzle 461 may be deionized water (DI Water, DIW).

However, as needed, the second nozzle 461 may also supply the first treatment liquid to the center region of the substrate W, or to an edge region (an example of a third location) of the substrate W.

The third liquid supply unit 470 may include a third nozzle 471, a third arm 472, a third movement shaft 473, and a third movement driver 474. The third liquid supply unit 470 may be positioned on the opposite side of the second liquid supply unit 460, relative to the support unit 420.

The third movement driver 474 may rotate the third movement shaft 473 in a direction perpendicular to the ground as the axis of rotation. One end of the third arm 472 may be connected to one end of the third movement shaft 473, such that the position of the other end of the third arm 472 may be changed by rotation of the third movement axis 473. At the other end of the third arm 472, a third nozzle 471 may be installed. Accordingly, the third nozzle 471 may be scan in (moving toward the center of the substrate W) or scan out (moving away from the center of the substrate W). The third nozzle 471 may be movable along an imaginary arc through the center of the substrate W when viewed from above.

The third nozzle 471 may supply a second treatment liquid to the middle region of the substrate W supported on the support unit 420 (an example of the second location). The second treatment liquid supplied by the third nozzle 471 may be an organic solvent including alcohol. For example, the second treatment liquid may be isopropyl alcohol (IPA).

However, depending on the need, the third nozzle 471 may also supply the second treatment liquid to the center region of the substrate W or to the edge region of the substrate W.

Additionally, the liquid treating chamber 400 may have a first nozzle waiting cup 481 and a second nozzle waiting cup 482. The first nozzle waiting cup 481 provides a first waiting space 481a, which may provide a space for the second nozzle 461 to wait when the second nozzle 461 is not processing the substrate W. Similar to the first nozzle waiting cup 481, the second nozzle waiting cup 482 provides a second waiting space 482b, and may provide a space for the third nozzle 471 to wait when the third nozzle 471 is not processing the substrate W.

The first and second nozzle waiting cups 481 and 482 may be connected with first and second cup exhaust lines CER1 and CER2, respectively, and the first and second cup exhaust lines CER1 and CER2 may be connected with first and second cup decompression devices EA2-1 and EA2-2, which may be pumps, to exhaust the first waiting space 481a and the second waiting space 482a. By exhausting the first waiting space 481a and the second waiting space 482a, droplets of the treatment liquid, and the like that are deposited at the ends of the second nozzle 461 and the third nozzle 471 may be recovered.

The downflow unit 490 may be installed on the upper portion of the housing 410. The downflow unit 490 may supply downflow DF to a space provided by the housing 410, such as an upper space 411 that is a processing space. The downflow unit 490 may be an assembly formed of a fan configured to be rotatable, a filter disposed at a lower side of the fan, and a frame in which the fan and filter are installed. The downflow unit 490 may be connected to an air supply line AL that connects to an air supply source AS. The air supply source AS may supply temperature- and humidity-controlled Clean Dry Air (CDA) to the downflow unit 490 via the air supply line AL.

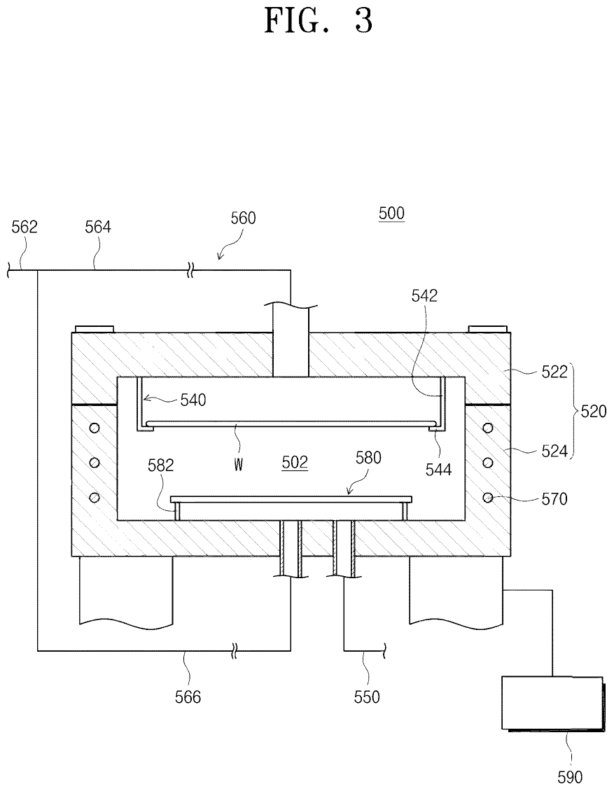

FIG. 3 is a diagram schematically illustrating the drying chamber of FIG. 1 according to the exemplary embodiment.

The drying chamber 500 may supply a supercritical fluid SCF to the substrate W that has been liquid treated in the liquid treating chamber 400 to dry treat the substrate W. In one exemplary embodiment, the drying chamber 500 removes the liquid on the substrate W by using the supercritical fluid SCF, which may be carbon dioxide in a supercritical state. The drying chamber 500 includes a body 520, a support body 540, a fluid supply unit 560, and a blocking plate 580.

The body 520 provides an interior space 502 in which the drying process is performed. The body 520 includes an upper body 522 and a lower body 524, and the upper body 522 and the lower body 524 are combined with each other to provide the interior space 502 described above. The upper body 522 is provided above the lower body 524. The upper body 522 is fixed in position, and the lower body 524 may be raised and lowered by a drive member 590, such as a cylinder. When the lower body 524 is spaced apart from the upper body 522, the interior space 502 is opened, and in this case, the substrate W is loaded or unloaded. During the process, the lower body 524 is in close contact with the upper body 522, so that the interior space 502 is sealed from the outside.

The drying chamber 500 includes a heater 570. According to one example, the heater 570 is located inside the wall of the body 520. The heater 570 heats the interior space 502 of the body 520 such that the supercritical fluid SCF supplied into the interior space 502 of the body 520 remains in a supercritical state.

The support body 540 supports the substrate W in the interior space 502 of the body 520. The support body 540 includes a fixing rod 542 and a cradle 544.

The fixing rod 542 is fixedly installed on the upper body 522 so as to protrude downward from the bottom surface of the upper body 522. The fixing rod 542 is provided so that a longitudinal direction thereof is the vertical direction. A plurality of fixing rods 542 is provided and is positioned to be spaced apart from each other. The fixing rods 542 are disposed so that the substrate W does not interfere with the fixing rods 542 when the substrate W is loaded into or unloaded from the space surrounded by the fixing rods 542. The cradle 544 is coupled to each of the fixing rods 542.

The cradle 544 extends from the lower end of the fixing rod 542 toward the space surrounded by the fixing rods 542. Due to the above-described structure, the substrate W loaded into the interior space 502 of the body 520 has an edge region placed on the cradle 544, and the entire upper surface region of the substrate W, the center region of the bottom surface of the substrate W, and a portion of the edge region of the bottom surface of the substrate W are exposed to the supercritical fluid SCF supplied to the interior space 502.

The fluid supply unit 560 supplies the supercritical fluid SCF to the interior space 502 of the body 520. In one example, the supercritical fluid SCF may be supplied to the interior space 502 in a supercritical state. Alternatively, the supercritical fluid SCF may be supplied to the interior space 502 in a gaseous state and phase-change to the supercritical state within the interior space 502. According to the example, the fluid supply unit 560 includes a main supply line 562, an upper branch line 564, and a lower branch line 566.

The upper branch line 564 and the lower branch line 566 are branched from the main supply line 562. The upper branch line 564 is coupled to the upper body 522 to supply the supercritical fluid SCF from the top of the substrate W placed on the support body 540. According to the example, the upper branch line 564 is coupled to the center of the upper body 522.

The lower branch line 566 is coupled to the lower body 524 to supply the supercritical fluid from the lower portion of the substrate W placed on the support body 540. According to the example, the lower branch line 566 is coupled to the center of the lower body 524. An exhaust line 550 is coupled to the lower body 524. The supercritical fluid in the interior space 502 of the body 520 is exhausted to the outside of the body 520 through the exhaust line 550.

A blocking plate 580 may be disposed in the interior space 502 of the body 520. The blocking plate 580 may be provided in a disk shape. The blocking plate 580 is supported by a support 582 so as to be spaced upward from the bottom surface of the body 520. The support 582 is provided in a rod shape, and a plurality of supports 582 is arranged to be spaced apart from each other by a predetermined distance. When viewed from above, the blocking plate 580 may be provided to overlap the outlet of the lower branch line 566 and the inlet of the exhaust line 550. The blocking plate 580 may prevent the supercritical fluid SCF supplied through the lower branch line 566 from being discharged directly toward the substrate W and damaging the substrate W.

Hereinafter, a substrate processing method according to an exemplary embodiment of the present invention will be described in detail. The substrate processing method described herein may be a manufacturing method that corresponds to some of the various processes required to process a substrate, such as a wafer, to manufacture a semiconductor device.

In addition, the controller 30 may control configurations of the substrate processing apparatus to enable the substrate processing apparatus to perform the substrate processing method described herein. For example, the controller 30 may generate a control signal to control the index module 10 and the processing module 20, and the various configurations that the index module 10 and the processing module 20 include.

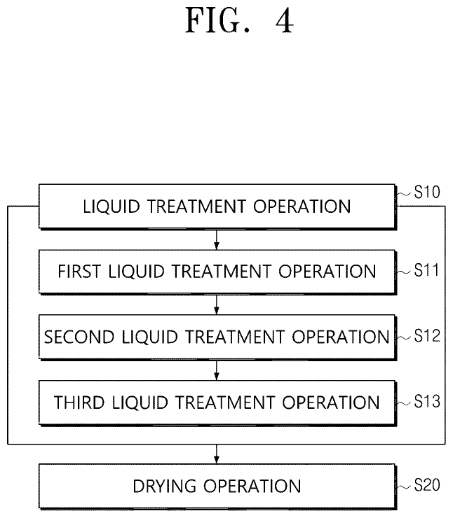

FIG. 4 is a flowchart schematically illustrating a substrate processing method according to an exemplary embodiment of the present invention.

Referring to FIG. 4, the substrate processing method according to the exemplary embodiment of the present invention may include a liquid treatment operation S10 and a dry treatment operation S20.

The liquid treatment operation S10 may be performed in the liquid treating chamber 400. The drying operation S20 may be performed in the drying chamber 500. The liquid treatment operation S10 may be performed by supplying a treatment liquid to the substrate W in the liquid treating chamber 400. The drying operation S20 may be performed by supplying the substrate W with a supercritical fluid SCF in the drying chamber 500 to dry the substrate W.

The liquid treatment operation S10 may include a first liquid treatment operation S11, a second liquid treatment operation S12, and a third liquid treatment operation S13. The first liquid treatment operation S11, the second liquid treatment operation S12, and the third liquid treatment operation S13 may be performed sequentially.

FIG. 5 is a diagram illustrating the liquid treating chamber performing the first liquid treatment operation of FIG. 4.

Referring to FIGS. 4 and 5, the first liquid treatment operation S11 may be a operation of supplying a first treatment liquid DIW to the center region and the middle region of the substrate W that is rotating while being supported on the support unit 420. The first treatment liquid DIW may clean the substrate W. In the first liquid treatment operation S11, the first nozzle 450 may supply the first treatment liquid DIW to the center region of the substrate W, and the second nozzle 461 may also supply the first treatment DIW to the middle region of the substrate W. When the first treatment liquid DIW is supplied to the substrate W, the first treatment liquid DIW is diffused through the rotation of the substrate W. In this case, when the first treatment liquid DIW is supplied only to the center region of the substrate W, the first treatment liquid DIW may not be uniformly diffused to the middle region and the edge region of the substrate W. When the first treatment liquid DIW is not diffused uniformly, a portion of the substrate W may be exposed to air. In this case, damage may occur to the pattern on the substrate W that is formed in the region exposed to the air.

Therefore, in the first liquid treatment operation S11 of the present invention, the first treatment liquid DIW is supplied to the center region and the middle region of the rotating substrate W, respectively, so that the first treatment liquid DIW may be spread uniformly and densely over the entire region of the substrate W.

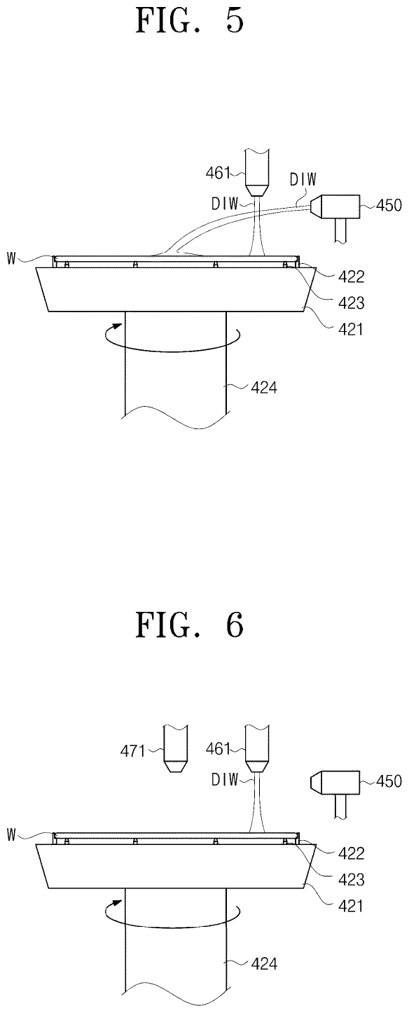

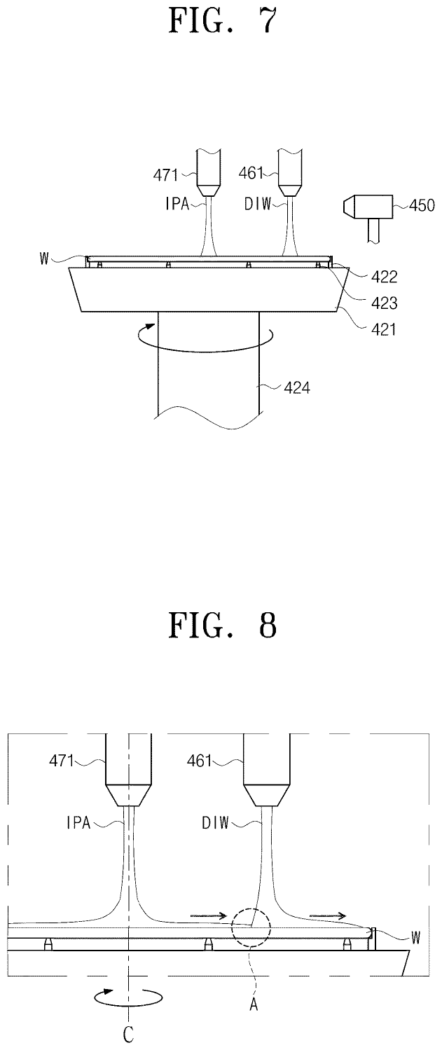

FIGS. 6 and 7 are diagrams illustrating a view of the liquid treating chamber performing the second liquid treatment operation of FIG. 4.

Referring to FIGS. 4, 6, and 7, the second liquid treatment operation S12 may include supplying a second treatment liquid IPA to the center region of the substrate W and supplying the first treatment liquid DIW to the middle region and/or the edge region. That is, supplying the second treatment liquid IPA to the center region of the substrate W and supplying the first treatment liquid DIW to the middle region and/or the edge region of the substrate W may be performed simultaneously.

In the second liquid treatment operation S12, the third nozzle 471 may move to the upper side of the center region of the substrate W and simultaneously stop supplying the first treatment liquid DIW (see FIG. 6), and simultaneously the third nozzle 471 may start supplying the second treatment liquid IPA (see FIG. 7).

Alternatively, the third nozzle 471 may move to the upper side of the center region of the substrate W, and after a period of time has elapsed, the third nozzle 471 may stop the supply of the first treatment liquid DIW from the first nozzle 450 simultaneously with the supply of the second treatment liquid IPA.

In short, the start of the supply of the second treatment liquid IPA from the third nozzle 471 and the stop of the supply of the first treatment liquid DIW from the first nozzle 450 may be simultaneously performed. Optionally, the stop of the supply from the first nozzle 450 may be a setting time (within about 1 second) later than the start of the supply of the second treatment liquid IPA. This is because, when the supply of the first treatment liquid DIW to the center region of the substrate W is stopped, the first treatment liquid DIW previously supplied to the center region of the substrate W may be scattered and flow toward the edge region of the substrate W, in which case the center region of the substrate W may be exposed to air.

Accordingly, in the present invention, the time that the center region of the substrate W may be exposed to the air may be minimized to minimize damage caused by natural drying to the pattern formed on the center region of the substrate W.

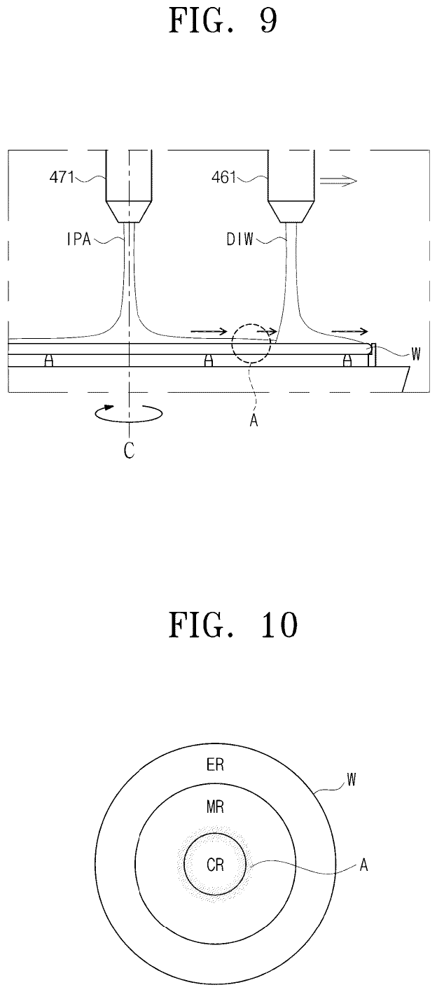

FIGS. 8 and 9 are diagrams illustrating the flow of the treatment liquid supplied to the substrate W, and the time of the movement of the second nozzle during the second liquid treatment operation of FIG. 4.

On the other hand, when the third nozzle 471 supplies the second treatment liquid IPA into the center region of the substrate W and the second nozzle 461 supplies the first treatment liquid DIW into the middle region of the substrate W, the second treatment liquid IPA may form a fringe film and the first treatment liquid DIW may form a bulk film. In addition, the fringe film formed by the second treatment liquid IPA may diffuse in the peripheral direction of the substrate W and come into contact with the bulk film formed by the first treatment liquid DIW.

In this case, when the second nozzle 461 continues to supply the first treatment liquid DIW in a fixed position (i.e., without changing the discharge position), liquid pushing phenomenon may occur at the point (point A) where the first treatment liquid DIW and the second treatment liquid IPA meet due to the Marangoni effect. The liquid pushing phenomenon may be a phenomenon in which the second treatment liquid IPA flowing in the peripheral direction of the substrate W is pushed in the direction toward the center of the substrate W at a moment. The liquid pushing phenomenon may occur when the first treatment liquid DIW and the second treatment liquid IPA are different types of treatment liquid, or more specifically, when the surface tension of the two treatment liquids is different. When the first treatment liquid DIW is deionized water and the second treatment liquid IPA is isopropyl alcohol, the surface tension of the first treatment liquid DIW is greater than that of the second treatment liquid IPA.

The liquid pushing phenomenon may occur to a greater extent when the contact time between the first treatment liquid DIW and the second treatment liquid IPA is about 2 seconds or longer. When the contact time is 2 seconds or less, the degree of contact between the second treatment liquid IPA and the first treatment liquid DIW is relatively small, and the continuously supplied second treatment liquid IPA continues to spread to the outer side of the substrate W and pushes the first treatment liquid DIW away. On the other hand, when the contact time exceeds 2 seconds, the degree of contact between the second treatment liquid IPA and the first treatment liquid DIW becomes larger, resulting in the liquid pushing phenomenon described above.

When this liquid pushing phenomenon occurs, the pattern of the substrate W is exposed to the air at point A, which is the point where a center region CR and a middle region MR of the substrate W meet, as illustrated in FIG. 10, and damage (e.g., pattern leaning phenomenon) may occur to the pattern formed at point A. This problem becomes more important as the pattern becomes very fine and the pattern difficulty increases (pattern difficulty increases from D1z to D1c+@).

Accordingly, in the exemplary embodiment of the present invention, the second treatment liquid IPA and the first treatment liquid DIW are supplied, and the second nozzle 461 which supplies the first treatment liquid DIW is scanned out as illustrated in FIG. 9. In addition, the second nozzle 461 continues to supply the first treatment liquid DIW while being scanned out. This prevents the liquid pushing phenomenon described above from occurring.

As described above, when the contact time between the fringe film and the bulk film is 2 seconds or longer, the liquid pushing phenomenon is more likely to occur. Furthermore, when the scan-out of the second nozzle 461 is started too quickly, there is a risk that the pattern of the substrate W is exposed to the air in the middle region MR and the edge region ER of the substrate W.

Accordingly, in the exemplary embodiment of the present invention, the second nozzle 461 is scanned out after a setting time has elapsed from the time at which the third nozzle 471 starts supplying the second treatment liquid IPA. The setting time may be set based on the time for the second treatment liquid IPA to reach the first treatment liquid DIW (e.g., the time it takes for the second treatment liquid IPA to be in first contact with the first treatment liquid DIW after the supply of the second treatment liquid IPA is initiated).

For example, the setting time may be set to a time after the supply of the second treatment liquid IPA is started, just before the fringe film and the bulk film are contacted, or within 2 seconds after the fringe film and the bulk film are contacted.

The setting time may be obtained in advance by changing the rotational speed of the substrate W, the supply flow rate per unit time of the second treatment liquid IPA, and the temperature of the second treatment liquid IPA, and by photographing an image using a vision or the like. The setting time may be calculated by processing a plurality of substrates W and calculating statistical values, such as average values and median values. The calculated setting time may be memorized by the controller 30.

In addition, the setting time may be set shorter as a rotation speed of the substrate W is higher. This is because the diffusion rate of the second treatment liquid IPA is high. Similarly, the supply flow rate per unit time of the second treatment liquid IPA supplied to the substrate W is higher, the setting time may be set to be shorter. Similarly, in this case, this is because the diffusion rate of the second treatment liquid IPA is fast.

Furthermore, it is not desirable that the second nozzle 461 is not moved until long before the fringe film and the bulk film meet. In this case, the patterns in the middle region MR and edge region ER of the substrate W may be exposed to the air. Therefore, the second nozzle 461 is preferably scanned out just before the fringe film and the bulk film meet, or within a threshold time (2 seconds) after the fringe film and the bulk film meet.

Furthermore, the movement speed of the second nozzle 461 is preferably equal to, or slower than, the diffusion speed of the second treatment liquid IPA. This is because when the second nozzle 461 moves too fast, the pattern may be similarly exposed to the air in some areas of the substrate W. Most preferably, the movement speed of movement of the second nozzle 461 is the same as the diffusion speed of the second treatment liquid IPA, otherwise, the speed of the second nozzle 461 may be set to a slower speed in a range that does not cause liquid pushing phenomenon.

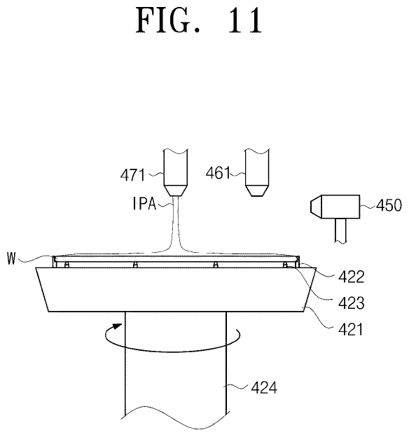

FIG. 11 is a diagram illustrating a view of the liquid treating chamber performing the third liquid treatment operation of FIG. 4.

Referring to FIGS. 4 and 11, in the third liquid treatment operation S30, the second nozzle 461 may be moved to the outer side of the substrate W and stop supplying the first treatment liquid DIW. In addition, the third nozzle 471 may continue to supply the second treatment liquid IPA. This allows the first treatment liquid DIW on the substrate W to be replaced by the second treatment liquid IPA, and a liquid film by the second treatment liquid IPA to be formed on the substrate W. Since the second treatment liquid IPA has relatively smaller surface tension than the first treatment liquid DIW, the second treatment liquid IPA easily penetrates between the fine patterns formed on the substrate W. Furthermore, since the second treatment liquid IPA has high solubility in carbon dioxide in the supercritical state, the second treatment liquid IPA helps the drying operation S20 described below to be carried out more appropriately.

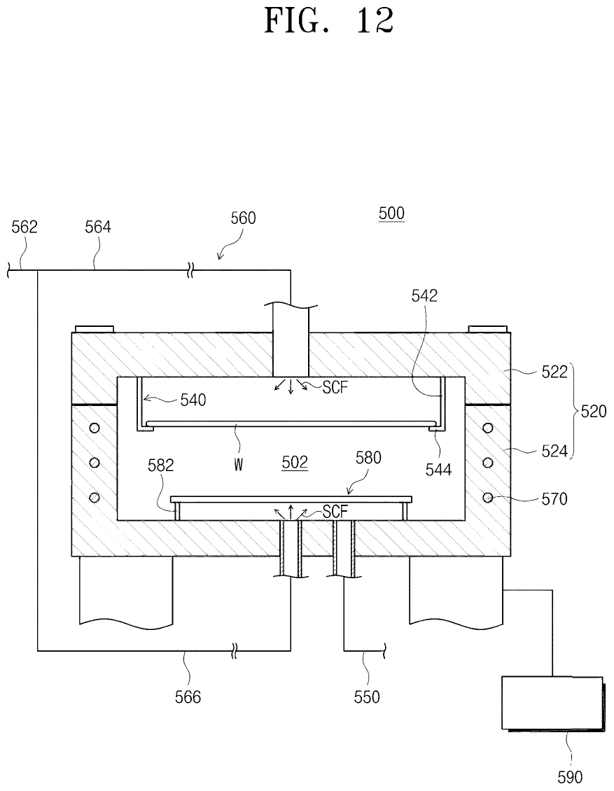

FIG. 12 is a diagram illustrating a view of the drying chamber performing the drying operation of FIG. 4.

Referring to FIGS. 4 and 12, the drying chamber 500 may dry the substrate W by supplying the substrate W with a supercritical fluid SCF. The substrate W loaded into the drying chamber 500 may be loaded with a liquid film formed on the top surface (patterned surface on which the pattern is formed) of the substrate W by the second treatment liquid IPA described above.

As described above, in the substrate processing method according to the exemplary embodiment of the present invention, the second liquid treatment operation S12 includes supplying the second treatment liquid IPA to the center region of the substrate W) and simultaneously supplying the first treatment liquid DIW to the middle region or edge region of the substrate, and initiating a scan out of the second nozzle 461 that supplies the first treatment liquid DIW just before the second treatment liquid IPA contacts the first treatment liquid DIW or within a threshold time after the second treatment liquid IPA contacts the first treatment liquid DIW. The second nozzle 461 continues to supply DIW while scanning out.

Thus, the time at which the pattern formed on the substrate W by the Marangoni effect described above is exposed to the air may be minimized, and in addition, the first treatment liquid DIW supplied to the substrate W may be replaced by the second treatment liquid IPA while maintaining the wetting state of the substrate W.

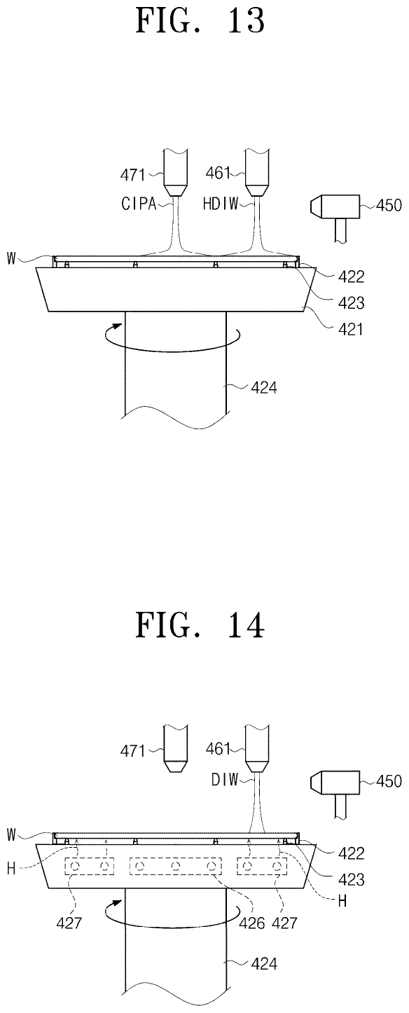

FIG. 13 is a diagram illustrating a view of a liquid treating chamber performing a substrate processing method according to another exemplary embodiment of the present invention.

Referring to FIG. 13, the aforementioned liquid pushing phenomenon is caused by the difference in surface tension between the first treatment liquid DIW and the second treatment liquid IPA, and as the difference in surface tension is larger, the liquid pushing phenomenon occurs more easily and largely. To alleviate this problem, the second treatment liquid IPA supplied to the center region of the substrate W may be cooled and supplied as a low-temperature second treatment liquid CIPA, and the first treatment liquid DIW supplied to the middle region of the substrate W may be heated and supplied as a high-temperature first treatment liquid DIW. Since the surface tension tends to be inversely proportional to the temperature of the liquid, the difference caused by the surface tension may be minimized by lowering the surface tension of the liquid supplied to the middle region of the substrate W and increasing the surface tension of the liquid supplied to the center region of the substrate W.

Further, the supply of the low-temperature cold secondary treatment liquid CIPA and the high-temperature first treatment liquid DIW may only occur after the previously described third nozzle 471 begins to supply a liquid and the setting time has elapsed, after which the third nozzle 471 may supply the original temperature second treatment liquid IPA and the second nozzle 461 may supply the original temperature first treatment liquid DIW.

Additionally, the second liquid supply unit 460 may include a chiller and the third liquid supply unit 470 may include a heater to supply the low-temperature secondary treatment liquid CIPA and the high-temperature primary treatment liquid DIW.

FIG. 14 is a diagram illustrating a liquid treating chamber according to another exemplary embodiment of the present invention, and a view of the liquid treating chamber performing a substrate processing method according to another exemplary embodiment.

In the foregoing, the present invention has been described based on the case where the temperature of the liquid is reduced to reduce the variation in surface tension as an example, but is not limited thereto. For example, the support unit 420 may further include a center heater 426 and an edge heater 427, wherein the heaters are configured to heat the substrate W. The edge heater 427 may deliver thermal energy H to the middle and edge regions of the substrate W, thereby increasing the temperature of the first treatment liquid DIW supplied to the substrate W, and thereby reducing the surface tension of the first treatment liquid DIW.

Furthermore, since heating of the first treatment liquid DIW by the edge heater 427 takes time, the heating of the first treatment liquid DIW may be pre-started before the secondary treatment liquid IPA is supplied.

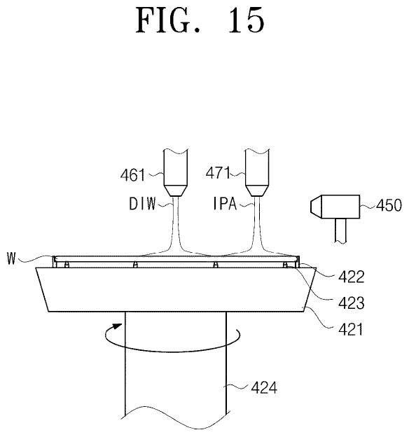

In the example described above, present invention has been described based on the case where the second liquid treatment operation S12 includes supplying the second treatment liquid IPA to the center region of the substrate W and supplying the first treatment liquid DIW to the middle region as an example, but is not limited thereto. As illustrated in FIG. 15, the aforementioned prevention of liquid pushing phenomenon through scan-out may be similarly applied even when the first treatment liquid DIW with high surface tension is supplied to the center region of the substrate W and the second treatment liquid IPA with low surface tension is supplied to the middle region. In other words, the prevention of liquid pushing phenomenon through scan-out according to the exemplary embodiment of the present invention may be applied equally/similarly to various fields of liquid treatment of the substrate W.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. A method of processing a substrate, the method comprising:
supplying a second treatment liquid of a different type from a first treatment liquid to a first location of a substrate while supplying the first treatment liquid to a second location of a rotating substrate, the first location being closer to a center of the substrate than the second location,
wherein the nozzle supplying the first treatment liquid is moved while continuing to supply the first treatment liquid after a setting time has elapsed from a time when the second treatment liquid is started to be supplied.

2. The method of claim 1, wherein the nozzle moves in a direction away from the center of the substrate while continuing to supply the first treatment liquid.

3. The method of claim 2, wherein the first treatment liquid and the second treatment liquid are provided to have different surface tension, and
the setting time is set based on a time for the second treatment liquid supplied to the first location to reach the second location.

4. The method of claim 3, wherein the setting time is set as a time immediately before the second treatment liquid supplied to the first location meets the first treatment liquid supplied to the second location, or a time within a threshold time after the first treatment liquid meets the second treatment liquid.

5. The method of claim 4, wherein the threshold time is a time period of no more than 2 seconds after the second treatment liquid supplied to the first location meets the first treatment liquid supplied to the second location.

6. The method of claim 1, wherein as a rotation speed of the substrate is higher, the setting time is set to be shorter.

7. The method of claim 1, wherein as a supply flow rate per unit time of the second treatment liquid supplied to the substrate is larger, the setting time is set to be shorter.

8. The method of claim 1, wherein the second treatment liquid is an organic solvent, and
the first treatment liquid is deionized water.

9. A manufacturing method, comprising:
a liquid treatment operation of supplying a treatment liquid to a rotating substrate to process the substrate; and
a drying operation of supplying a supercritical fluid to the substrate to process the substrate, after the liquid treatment operation,
wherein the liquid treatment operation includes:
a first liquid treatment operation of supplying a first treatment liquid to a first location of the rotating substrate and a second position that is farther from a center of the substrate than the first position; and
a second liquid treatment operation of supplying a second treatment liquid having different surface tension from the first treatment liquid to the first location of the rotating substrate, and supplying the first treatment liquid to the second location of the rotating substrate, and
the second liquid treatment operation includes, after the supply of the second treatment liquid has begun and a setting time has elapsed, moving a nozzle supplying the first treatment liquid in a direction away from the center of the substrate while supplying the first treatment liquid.

10. The manufacturing method of claim 9, wherein the setting time is set based on a time for the second treatment liquid supplied to the first location to reach the second location.

11. The manufacturing method of claim 10, wherein the setting time is set as a time immediately before the second treatment liquid supplied to the first location meets the first treatment liquid supplied to the second location, or a time within a threshold time after the first treatment liquid meets the second treatment liquid.

12. The manufacturing method of claim 11, wherein the threshold time is a time within 2 seconds after the second treatment liquid supplied to the first location meets the first treatment liquid supplied to the second location.

13. The manufacturing method of claim 9, wherein a movement speed of the nozzle in the second liquid treatment operation is equal to or lower than a diffusion rate of the second treatment liquid supplied to the first location in the second liquid treatment operation.

14. The manufacturing method of claim 9, wherein the liquid treatment operation further includes a third liquid treatment operation of supplying the second treatment liquid to the first location of the rotating substrate to form a liquid film, after the second liquid treatment operation.

15. The manufacturing method of claim 9, wherein the first treatment liquid has greater surface tension than the second treatment liquid.

16. The manufacturing method of claim 9, wherein the first treatment liquid is deionized water, and
the second treatment liquid is isopropyl alcohol.

17. A control method of a substrate processing apparatus, the substrate processing apparatus including: a substrate support chuck for supporting and rotating a substrate; a first nozzle for supplying a first treatment liquid to the substrate supported on the substrate support chuck; a second nozzle for supplying the first treatment liquid to the substrate supported on the substrate support chuck; and a third nozzle for supplying a second treatment liquid of a type different from the first treatment liquid to the substrate supported on the substrate support chuck, the control method comprising:
supplying, by the first nozzle, the first treatment liquid to a center region of the substrate supported and rotated on the substrate support scale, and supplying, by the second nozzle, the first treatment liquid to a middle region of the substrate supported and rotated on the substrate support chuck, the middle region being a region farther from the center of the substrate than the center region;
moving the third nozzle to a top side of the center region of the substrate;
supplying, by the third nozzle, the second treatment liquid to the center region of the substrate; and
after the third nozzle has begun to supply the second treatment liquid and a setting time has elapsed, moving the second nozzle in a direction away from the center of the substrate, in which the second nozzle continues to supply the first treatment liquid while moving.

18. The control method of claim 17, wherein the setting time is set as a time immediately before the second treatment liquid supplied to the center region meets the first treatment liquid supplied to the middle region, or a time within a threshold time after the first treatment liquid meets the second treatment liquid.

19. The control method of claim 18, wherein the threshold time is a time within 2 seconds after the second treatment liquid supplied to a first location meets the first treatment liquid supplied to a second location that is farther from a center of the substrate than the first position.

20. The control method of claim 16, wherein the second nozzle moves along an imaginary arc through a center of the substrate W when viewed from above.
